(19) United States
(12) Patent Application Publication
(10) Pub. No.: US 2026/0188269 A1
(43) Pub. Date: Jul. 2, 2026

(54) DISPLAY DEVICE, ELECTRONIC DEVICE USING THE SAME AND INSPECTING SYSTEM FOR DISPLAY DEVICE

(71) Applicant: Samsung Display Co., Ltd., Yongin-si (KR)

(72) Inventors: Hee Woong PARK, Yongin-si (KR); Jun Young KO, Yongin-si (KR); Han Su CHO, Yongin-si (KR)

(21) Appl. No.: 19/352,596

(22) Filed: Oct. 8, 2025

(30) Foreign Application Priority Data
Dec. 30, 2024 (KR) 10-2024-0199882

(51) Int. Cl. G09G 3/34; G09G 3/00

(52) U.S. Cl. CPC G09G 3/3413; G09G 3/006; G09G 2310/08; G09G 2320/041; G09G 2330/021; G09G 2354/00

(57) ABSTRACT

A display device includes a display panel; a fingerprint sensing circuit embedded into the display panel and configured to sense a user's fingerprint; a sensor control circuit configured to receiving a temperature sensing signal from a temperature sensing element of the fingerprint sensing circuit, and to generate temperature data in real time; and a display driving circuit configured to: receive and store first to (n)th reference temperature information and inspection pattern image data for each temperature range from the outside, analyze temperature information and a temperature change for the display panel in real time by receiving the temperature data in real time, select one of the inspection pattern image data based on a comparison result of the temperature information for the display panel and the first to (n)th reference temperature information, and display the one of the inspection pattern image data on the display panel as an image.

### CROSS-REFERENCE TO RELATED APPLICATION

The present application claims priority to and the benefit of Korean Patent Application No. 10-2024-0199882, filed on Dec. 30, 2024, in the Korean Intellectual Property Office, the entire disclosure of which is incorporated herein by reference.

### BACKGROUND

### 1. Field

The present disclosure relates to a display device, an electronic device using the same, and an inspecting system for the display device.

### 2. Description of the Related Art

With the advancement of the information age, the demand for a display device for displaying an image has increased with various forms. For example, the display device has been applied to various electronic devices such as a smart phone, a digital camera, a laptop computer, a navigator and a smart television.

The display device may be a flat panel display device such as a liquid crystal display device, a field emission display device and an organic light emitting display device. The light emitting display device of the flat panel display device may include a light emitting element in which each of pixels of a display panel may self-emit light, thereby displaying an image even without a backlight unit that provides light to the display panel.

The display panel is manufactured by forming pixels and embedded circuits according to resolution in cell areas of a mother glass, and modularizing each cell area into the display panel by separating each cell area. A circuit board in which a circuit film and driving circuits are packaged is connected to the display panel, so that display devices of a state before being manufactured are formed.

During the inspection process of display devices, an image of the display panel is captured with a precision camera to inspect image display characteristics, such as image quality, and pixel defects. However, since a temperature of the display panel is increased while an image is displayed during the inspection process, a problem occurs in that reliability of inspection quality is deteriorated, such as an inspection result is distorted and an error occurs by a temperature change.

The above information disclosed in this Background section is only for enhancement of understanding of the background of the invention and therefore it may contain information that does not form.

### SUMMARY

Aspects of some embodiments of the present disclosure are directed to a display device, an electronic device using the same, and an inspecting system for the display device, in which a temperature sensing signal or temperature data is checked through a temperature sensing element formed in a fingerprint sensing circuit unit of a display panel, and the display panel may be inspected to correspond to a temperature change of the display panel.

Aspects of some embodiments of the present disclosure are directed to a display device, an electronic device using the same, and an inspecting system for the display device, in which a temperature change of a display panel is monitored in real time during an inspection period and a temperature change period and a change range of the display panel may be adjusted by varying an inspection pattern image in accordance with a temperature of the display panel.

The objects of the present disclosure are not limited to those mentioned above and additional objects of the present disclosure, which are not mentioned herein, will be clearly understood by those skilled in the art from the following description of the present disclosure.

According to some embodiment of the present disclosure, there is provided a display device including: a display panel displaying an image through a pixel of a display area; a fingerprint sensing circuit embedded into the display panel and configured to sense a user's fingerprint; a sensor control circuit configured to receiving a temperature sensing signal from a temperature sensing element of the fingerprint sensing circuit, and to generate temperature data in real time; and a display driving circuit configured to: receive and store first to (n)th reference temperature information and inspection pattern image data for each temperature range from the outside, analyze temperature information and a temperature change for the display panel in real time by receiving the temperature data in real time, select one of the inspection pattern image data based on a comparison result of the temperature information for the display panel and the first to (n)th reference temperature information, and display the one of the inspection pattern image data on the display panel as an image.

In some embodiments, the fingerprint sensing circuit is embedded into a non-display area on one side or a rear surface of the display panel or in a direction of the rear surface of the display panel, the fingerprint sensing circuit further includes a fingerprint sensing pad configured to sense light reflected from a user's finger by using light emitting elements and light receiving elements, which are arranged in a matrix structure, and the fingerprint sensing circuit is further configured to supply light sensing signals of the fingerprint sensing pad and the temperature sensing signal of the temperature sensing element to the sensor control circuit.

In some embodiments, the display driving circuit is further configured to store the first to (n)th reference temperature information and the inspection pattern image data for each temperature range, which are received from an external inspection processing circuit during an inspection period, in an internal memory or a separate external memory, and the inspection pattern image data for each temperature range includes inspection pattern image data of a high gray scale, an intermediate or mixed gray scale, and a low gray scale, which are selected based on the temperature range.

In some embodiments, the display driving circuit is configured to: analyze the temperature range of the temperature information according to the temperature data compared to the first to (n)th reference temperature information, select at least one inspection pattern image data from the inspection pattern image data of a preset gray scale range based on the temperature range of the display panel, which is analyzed in real time, and control an image display timing so that an image according to the at least one inspection pattern image data is displayed on the display area.

In some embodiments, the display driving circuit is further configured to: transmit a first temperature code to an inspection processing circuit of an inspection device in response to a temperature of the temperature information for the display panel being lower than a preset first reference temperature, and drive pixels of the display area so that inspection pattern image data of a preset high gray scale among the inspection pattern image data is displayed on the display area in response to the temperature of the temperature information for the display panel being in a first reference temperature range, which is a range from the preset first reference temperature to less than a second reference temperature, and transmit a second temperature code according to the first reference temperature range to the inspection processing circuit.

In some embodiments, the display driving circuit is configured to: drive the pixels of the display area so that inspection pattern image data of a preset intermediate or mixed gray scale among the inspection pattern image data is displayed on the display area when the temperature of the temperature information for the display panel is detected in a second reference temperature range, which is a range from the second reference temperature to less than a third reference temperature, and transmits a third temperature code according to the second reference temperature range to the inspection processing circuit, and drive the pixels of the display area so that inspection pattern image data of a preset low gray scale among the inspection pattern image data is displayed on the display area in response to the temperature of the temperature information for the display panel being in a third reference temperature range, which is a range from the third reference temperature to less than a fourth reference temperature, and transmit a fourth temperature code according to the third reference temperature range to the inspection processing circuit.

In some embodiments, the display driving circuit is configured to transmit a fifth temperature code to the inspection processing circuit in response to the temperature of the temperature information for the display panel being in a fourth reference temperature range above a preset fourth reference temperature, and to stop an image display operation based on a power control operation of the inspection processing circuit.

According to some embodiment of the present disclosure, there is provided an electronic device including: a display device displaying an image; an image signal processor configured to control an image display timing of the display device; and a power module configured to provide a power signal to the display device, wherein the display device includes: a display panel configured to display an image through a pixel of a display area; a fingerprint sensing circuit embedded into the display panel and configured to sense a user's fingerprint; a sensor control circuit configured to receive a temperature sensing signal from a temperature sensing element of the fingerprint sensing circuit and to generate temperature data in real time; and a display driving circuit configured to: receive and store first to (n)th reference temperature information and inspection pattern image data for each temperature range from the outside, analyze temperature information and a temperature change for the display panel in real time by receiving the temperature data in real time, select one of the inspection pattern image data based on a comparison result of the temperature information for the display panel and the first to (n)th reference temperature information, and display the one of the selected inspection pattern image data on the display panel as an image.

According to some embodiment of the present disclosure, there is provided an inspecting system for a display device, the inspecting system including: a chamber establishing and maintaining an external inspection environment of the display device; a temperature control device configured to control an internal temperature of the chamber; a loading plate on which the display device is loaded; an input/output terminal unit electrically connected to a circuit board of the display device; an inspection processing circuit configured to supply inspection pattern image data of a preset gray scale range and timing signals to the display device through the input/output terminal unit, and to receive temperature data from the display device; an image detection device configured to photograph a display image of the display device; and a quality analysis device configured to: inspect whether the display device is good, supply a temperature control signal to the temperature control device during an image display characteristics inspection period of the display device to control the internal temperature of the chamber within a preset inspection reference temperature range, stop analyzing image display characteristics of the display device in response to an inspection stop signal being received from the inspection processing circuit, and control the internal temperature of the chamber by supplying a cooling control signal for lowering the internal temperature of the chamber to be lower than a preset reference temperature to the temperature control device.

In some embodiments, the display device includes: a display panel configured to display an image through a pixel of a display area; a fingerprint sensing circuit embedded into the display panel and configured to sense a user's fingerprint; a sensor control circuit configured to receive a temperature sensing signal from a temperature sensing element of the fingerprint sensing circuit and to generate temperature data in real time; and a display driving circuit configured to receive and storing first to (n)th reference temperature information and inspection pattern image data for each temperature range from the outside, and to analyze temperature information and a temperature change for the display panel in real time by receiving the temperature data in real time, wherein the display driving circuit is further configured to select one of the inspection pattern image data based on a comparison result of the temperature information for the display panel and the first to (n)th reference temperature information, and to display the one of the inspection pattern image data on the display panel as an image.

In some embodiments, the display driving circuit is further configured to store the first to (n)th reference temperature information and the inspection pattern image data for each temperature range, which are received from the inspection processing circuit during an inspection period, in an internal memory or a separate external memory, and the inspection pattern image data for each temperature range include inspection pattern image data of a high gray scale, an intermediate or mixed gray scale, and a low gray scale, which are selected based on the temperature range.

In some embodiments, the display driving circuit is configured to: analyze the temperature range of the temperature information according to the temperature data compared to the first to (n)th reference temperature information, select at least one inspection pattern image data from the inspection pattern image data of a preset gray scale range based on the temperature range of the display panel, which is analyzed in real time, and control an image display timing so that an image according to the selected inspection pattern image data is displayed on the display area.

In some embodiments, the inspection processing circuit is configured to: receive the temperature data in real time from the sensor control circuit through the input/output terminal unit, analyze the temperature information and the temperature change of the temperature data in real time, and block a power supply of the display device based on a temperature analysis result.

In some embodiments, the display driving circuit is configured to: transmit a first temperature code to an inspection processing circuit of an inspection device in response to a temperature of the temperature information for the display panel being at a temperature lower than a preset first reference temperature, and drive pixels of the display area so that inspection pattern image data of a preset high gray scale among the inspection pattern image data is displayed on the display area in response to the temperature of the temperature information for the display panel being in a first reference temperature range, which is a range from the first reference temperature to less than a second reference temperature, and transmit a second temperature code according to the first reference temperature range to the inspection processing circuit.

In some embodiments, the display driving circuit is configured to: drive the pixels of the display area so that inspection pattern image data of a preset intermediate or mixed gray scale among the inspection pattern image data is displayed on the display area, in response to the temperature of the temperature information for the display panel being in a second reference temperature range, which is a range from the second reference temperature to less than a third reference temperature, transmit a third temperature code according to the second reference temperature range to the inspection processing circuit, and drive the pixels of the display area so that inspection pattern image data of a preset low gray scale among the inspection pattern image data is displayed on the display area in response to the temperature of the temperature information for the display panel being in a third reference temperature range, which is a range from the third reference temperature to less than a fourth reference temperature, and transmit a fourth temperature code according to the third reference temperature range to the inspection processing circuit.

In some embodiments, the display driving circuit is configured to: transmit a fifth temperature code to the inspection processing circuit in response the temperature of the temperature information for the display panel being in a fourth reference temperature range above a preset fourth reference temperature, and stop an image display operation based on a power control operation of the inspection processing circuit.

In the display device, the electronic device using the same, and the inspecting system for the display device according to some embodiments of the present disclosure, a temperature sensing signal or temperature data is checked in real time using a temperature sensing element embedded into a display panel, so that a temperature of the display panel may be checked and analyzed easily and reliably even without additional action or cost for an inspection period.

Also, in the display device, the electronic device using the same, and the inspecting system for the display device according to some embodiments of the present disclosure, an inspection pattern image is varied in accordance with (e.g., based on) a temperature change range of a display panel, so that a temperature change period and a change range of the display panel may be adjusted, whereby an inspection period may be efficiently adjusted and reliability of an inspection result may be enhanced.

The effects according to some embodiments of the present disclosure are not limited to those mentioned above and more various effects are included in the following description of the present disclosure.

### BRIEF DESCRIPTION OF THE DRAWINGS

The above and other aspects and features of the present disclosure will become more apparent by describing in detail embodiments thereof with reference to the attached drawings, in which:

FIG. 1 is a block diagram illustrating an electronic device according to some embodiments of the present disclosure;

FIG. 2 illustrates schematic diagrams of electronic devices according to some embodiments of the present disclosure;

FIG. 3 is a perspective view illustrating a display device according to some embodiments of the present disclosure;

FIG. 4 is a cross-sectional view showing a display device according to some embodiments of the present disclosure;

FIG. 5 is a plan view illustrating a display unit of a display device according to some embodiments of the present disclosure;

FIG. 6 is one side cross-sectional view illustrating an inspection device for a display device according to some embodiments of the present disclosure;

FIG. 7 is a perspective view illustrating a loading state of a display device shown in FIG. 6 and an inspection process using an inspection device and an analysis device, according to some embodiments of the present disclosure;

FIG. 8 is a schematic block diagram briefly illustrating components of the inspection device shown in FIG. 7, according to some embodiments of the present disclosure;

FIG. 9 is a flow chart illustrating an inspecting method of an image display of a display device according to some embodiments of the present disclosure; and

FIG. 10 is a graph illustrating a temperature change of a display panel and first to fourth reference temperature ranges some embodiments according to some embodiments of the present disclosure.

### DETAILED DESCRIPTION

The present disclosure will now be described more fully hereinafter with reference to the accompanying drawings, in which preferred embodiments of the present disclosure are shown. This disclosure may, however, be embodied in different forms and should not be construed as limited to the embodiments set forth herein. Rather, these embodiments are provided so that this disclosure will be thorough and complete, and will filly convey the scope of the present disclosure to those skilled in the art.

It will also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present disclosure. Similarly, the second element could also be termed the first element.

Each of the features of the various embodiments of the present disclosure may be combined or combined with each other, in part or in whole, and technically various interlocking and driving are possible. Each embodiment may be implemented independently of each other or may be implemented together in an association.

Hereinafter, detailed embodiments will be described with reference to the accompanying drawings.

A display device according to some embodiments of the present disclosure may be applied to various electronic devices. The electronic device according to some embodiments includes the display device, and may further include modules or devices having other additional functions in addition to the display device.

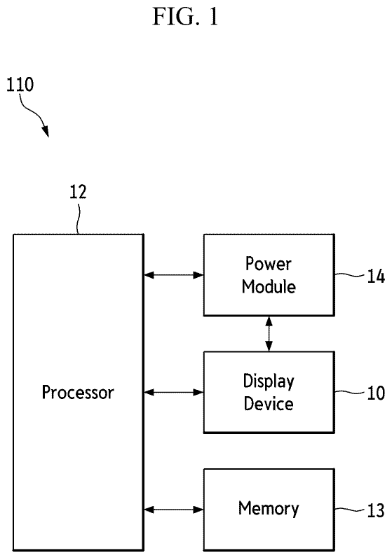

FIG. 1 is a block diagram illustrating an electronic device according to some embodiments of the present disclosure.

Referring to FIG. 1, an electronic device 110 according to some embodiments may include a display device 10, a processor 12, a memory 13, and a power module 14.

The processor 12 may include at least one of a central processing unit (CPU), an application processor (AP), a graphic processing unit (GPU), a communication processor (CP), an image signal processor (ISP), or a controller.

Data information utilized for the operation of the processor 12 or the display device 10 may be stored in the memory 13. When the processor 12 executes an application stored in the memory 13, an image data signal and/or an input control signal is transmitted to the display device 10, and the display device 10 may process the received signal and output image information through a display screen.

The power module 14 may include a power supply module such as a power adapter or a battery device, and a power conversion module that converts a power source supplied by the power supply module to generate a power source utilized for the operation of the electronic device 110.

At least one of the respective components of the above-described electronic device 110 may be included in the display device according to the above-described embodiments. Also, some of the individual modules functionally included in one module may be included in the display device 10, and others thereof may be provided separately from the display device 10. For example, the display device 10 includes a display panel, and the processor 12, the memory 13 and the power module 14 may be provided as other devices in the electronic device 110 not the display device 10.

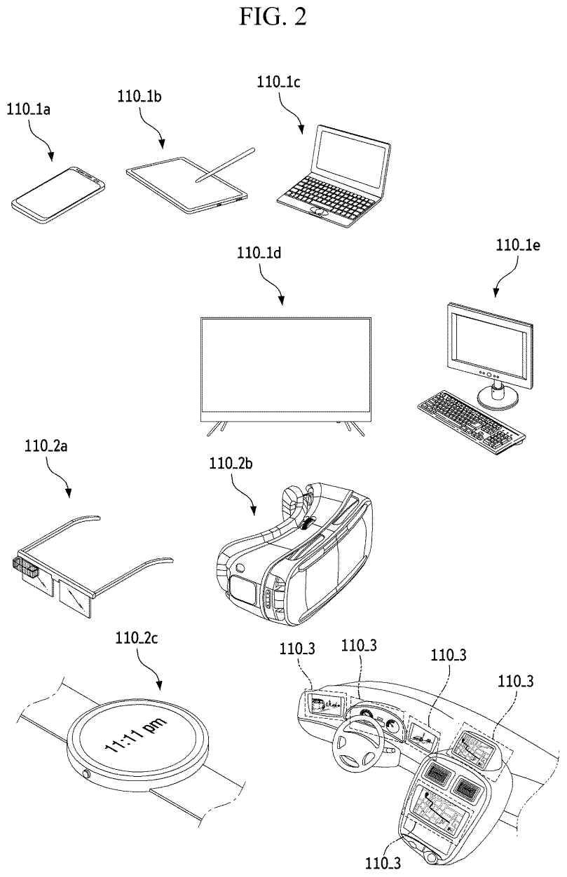

FIG. 2 illustrates schematic diagrams of electronic devices according to some embodiments of the present disclosure.

Referring to FIG. 2, various electronic devices 110 to which the display devices 10 according to some embodiments are applied may include not only electronic devices for image display, such as a smart phone 110_1a, a tablet PC 110_1b, a laptop 110_1c, a TV 110_1d, and a desk monitor 110_1e, but also wearable electronic devices including display modules such as smart glasses 110_2a, a head mounted display 110_2b, and a smart watch 110_2c, and a vehicle electronic device 110_3 including display modules such as a vehicle dashboard, a center fascia, a center information display (CID) arranged on the dashboard, and a room mirror display. In addition, the display device 10 may be applied as a display member of a television, a laptop, a monitor, an advertising board, or Internet of Things (IOT).

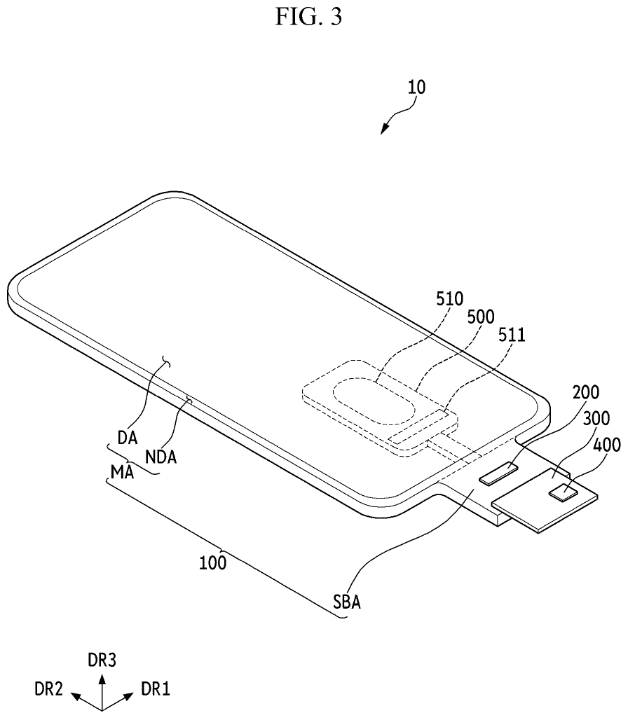

FIG. 3 is a perspective view illustrating a display device according to some embodiments of the present disclosure.

Referring to FIG. 3, the display device 10 applied to the electronic device 110 may be formed in a planar shape similar to a rectangular shape depending on a shape of a display unit of the electronic device 110. For example, the display device 10 have a planar shape similar to a rectangular shape having a short side in a first direction DR1 and a long side in a second direction DR2. A corner where the short side in the first direction DR1 and the long side in the second direction DR2 meet may be rounded to have a curvature or formed at a right angle. The planar shape of the display device 10 may have another polygonal shape or a shape similar to a circular shape or an oval shape without being limited to the rectangular shape.

The display device 10 according to some embodiments may be a light emitting display device such as an organic light emitting display device using an organic light emitting diode, a quantum dot light emitting display device including a quantum dot light emitting layer, an inorganic light emitting display device including an inorganic semiconductor, and a micro or nano light emitting display device using a micro or nano light emitting diode (micro or nano LED). The following description will be based on that the display device 10 is an organic light emitting display device, but the present disclosure is not limited thereto.

The display device 10 may include a display panel 100, a display driving circuit 200, a circuit board 300, a sensor control circuit 400, and a fingerprint sensing circuit unit (also simply referred to herein as a fingerprint sensing circuit) 500.

The display panel 100 may include a main area MA and a sub-area SBA.

The main area MA may include a display area DA including pixels for displaying an image, and a non-display area NDA arranged around the display area DA. The display area DA may emit light from a plurality of light emission areas or a plurality of opening areas. For example, the display panel 100 may include a pixel circuit including switching elements, a pixel defining layer defining a light emission area or an opening area, and a self-light emitting element.

For example, the self-light emitting element may include at least one of an organic light emitting diode including an organic light emitting layer, a quantum dot LED including a quantum dot light emitting layer, an inorganic LED including an inorganic semiconductor, or a micro LED, but is not limited thereto.

The non-display area NDA may be an outer area of the display area DA. The non-display area NDA may be defined as an edge area of the main area MA of the display panel 100. The non-display area NDA may include a gate driver supplying gate signals to gate lines, and fan-out lines connecting the display driving circuit 200 with the display area DA.

The sub-area SBA may extend from one side of the main area MA. The sub-area SBA may include a flexible material capable of being subjected to bending, folding, rolling, and the like. For example, when the sub-area SBA is bent, the sub-area SBA may overlap the main area MA in a thickness direction (e.g., a third direction DR3). The sub-area SBA may include the display driving circuit 200, and a pad portion connected to the circuit board 300. In some examples, the sub-area SBA may be omitted, and the display driving circuit 200 and the pad portion may be arranged in the non-display area NDA.

Driving circuit units including the display driving circuit 200, the circuit board 300, and the sensor control circuit 400 are electrically connected to the non-display area NDA, respectively.

The display driving circuit 200 controls an image display operation of each pixel by supplying a data voltage and driving control signals to the pixels arranged in the display area DA of the display panel 100. For example, the display driving circuit 200 stores inspection pattern image data supplied from an inspection processing circuit of an inspection device when image display of the display panel 100 is inspected, converts the inspection pattern image data into analog data voltages, and supplies the converted analog data voltages to the pixels of the display area DA. The display driving circuit 200 controls an image display timing by supplying scan signals to the pixels of the display area DA, so that the pixels display images sequentially.

The fingerprint sensing circuit unit 500 is embedded into the non-display area NDA on any one side or a front surface of the display panel 100 or in a direction of a rear surface of the display panel 100 and configured to sense a user's fingerprint. The fingerprint sensing circuit unit 500 includes a fingerprint sensing pad (e.g., a light sensing pad) 510 and at least one temperature sensing element 511.

The fingerprint sensing pad 510 of the fingerprint sensing circuit unit 500 senses light reflected from the user's finger by using light emitting elements and light receiving elements, which are arranged in a matrix structure, and supplies light sensing signals to the sensor control circuit 400.

The temperature sensing element 511 of the fingerprint sensing circuit unit 500 may include a thermistor, a resistance temperature detector (RTD), and the like. The temperature sensing element 511 senses a rear surface temperature of the display panel 100 or the fingerprint sensing pad 510 and supplies a temperature sensing signal to the sensor control circuit 400.

The sensor control circuit 400 may be packaged on the circuit board 300. The sensor control circuit 400 modulates (e.g., converts) an analog temperature sensing signal into digital temperature data and calculates rear surface temperature information of the fingerprint sensing pad 510 or the display panel 100 in real time. The sensor control circuit 400 sequentially drives the light emitting elements arranged on the fingerprint sensing pad 510 and receives light sensing signals through the light receiving elements. In such examples, the sensor control circuit 400 may adjust light sensing sensitivity of the light receiving elements arranged on the fingerprint sensing pad 510 based on the rear surface temperature of the fingerprint sensing pad 510 or the display panel 100. As used herein, the term “real time” may refer to an imperceptibly short period of time (e.g., in milliseconds or microseconds), and data processed in real time may be available almost immediately as feedback.

The sensor control circuit 400 detects the user's fingerprint shape by converting and arranging the light sensing signals of the light receiving elements into light sensing data in at least one frame unit. In addition, the sensor control circuit 400 may correct the light sensing data based on the rear surface temperature of the fingerprint sensing pad 510 or the display panel 100 and detect the user's fingerprint shape. In such examples, the sensor control circuit 400 is formed in a shape of an integrated circuit, and may be integrally formed with the integrated circuit such as the display driving circuit 200 or a touch driving circuit.

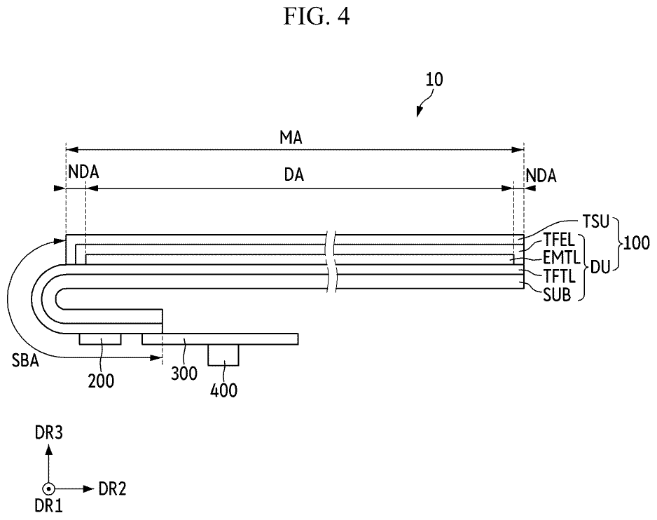

FIG. 4 is a cross-sectional view illustrating a display device according to some embodiments of the present disclosure.

Referring to FIG. 4, the display panel 100 may include a display unit DU and a touch sensing unit TSU. The display unit DU may include a substrate SUB, a thin film transistor layer TFTL, a light emitting element layer ETML, and an encapsulation layer TFEL.

The substrate SUB may be a base substrate or a base member. The substrate SUB may be a flexible substrate capable of being subjected to bending, folding, rolling, or the like. For example, the substrate SUB may include a polymer resin such as polyimide (PI), but is not limited thereto. For another example, the substrate SUB may include a glass material or a metal material.

The thin film transistor layer TFTL may be arranged on the substrate SUB. The thin film transistor layer TFTL may include a plurality of thin film transistors constituting a pixel circuit of pixels. The thin film transistor layer TFTL may further include gate lines, data lines DL, power lines, gate control lines, fan-out lines connecting the display driving circuit 200 to the data lines DL, and lead lines connecting the display driving circuit 200 to the pad portion. Each of the thin film transistors may include a semiconductor area, a source electrode, a drain electrode and a gate electrode. For example, when a scan driver (e.g., a gate driver) is formed on one side of the non-display area NDA of the display panel 100, the scan driver may include thin film transistors.

The thin film transistor layer TFTL may be arranged in the display area DA, the non-display area NDA and the sub-area SBA. The thin film transistors, the gate lines, the data lines DL, and the power lines of the pixels of the thin film transistor layer TFTL may be arranged in the display area DA. The gate control lines and the fan-out lines of the thin film transistor layer TFTL may be arranged in the non-display area NDA. The lead lines of the thin film transistor layer TFTL may be arranged in the sub-area SBA.

A light emitting element layer EMTL may be arranged on the thin film transistor layer TFTL. The light emitting element layer EMTL may include a plurality of light emitting elements that include a pixel electrode, a light emitting layer, and a common electrode, which are sequentially stacked to emit light, and a pixel defining layer for defining pixels. The plurality of light emitting elements of the light emitting element layer EMTL may be arranged in the display area DA.

The light emitting layer may be an organic light emitting layer that includes an organic material. The light emitting layer may include a hole transporting layer, an organic light emitting layer, and an electron transporting layer. When the pixel electrode receives a voltage through the thin film transistor of the thin film transistor layer TFTL and the common electrode receives a cathode voltage, holes and electrons may move to the organic light emitting layer through the hole transporting layer and the electron transporting layer, respectively, and may be combined with each other in the organic light emitting layer to emit light. For example, the pixel electrode may be an anode electrode, and the common electrode may be a cathode electrode, but the present disclosure is not limited thereto.

As another example, the plurality of light emitting elements may include a quantum dot light emitting diode including a quantum dot light emitting layer, an inorganic light emitting diode including an inorganic semiconductor, or a micro light emitting diode.

The encapsulation layer TFEL may cover an upper surface and a side of the light emitting element layer EMTL, and may protect the light emitting element layer EMTL. The encapsulation layer TFEL may include at least one inorganic layer and at least one organic layer to encapsulate the light emitting element layer EMTL.

The touch sensing unit TSU may be arranged on the encapsulation layer TFEL. The touch sensing unit TSU may include a plurality of touch electrodes for sensing a user's touch in a capacitance manner, and touch lines for connecting the plurality of touch electrodes with the sensor control circuit 400 or the touch driver. For example, the touch sensing unit TSU may sense the user's touch in a mutual capacitance manner or a self-capacitance manner.

As another example, the touch sensing unit TSU may be arranged on a separate substrate arranged on the display unit DU. In such examples, the substrate supporting the touch sensing unit TSU may be a base member for encapsulating the display unit DU.

The plurality of touch electrodes of the touch sensing unit TSU may be arranged in a touch sensor area that overlaps the display area DA. The touch lines of the touch sensing unit TSU may be arranged in a touch peripheral area that overlaps the non-display area NDA.

The sub-area SBA of the display panel 100 may extend from one side of the main area MA. The sub-area SBA may include a flexible material capable of being subjected to bending, folding, rolling, and the like. For example, when the sub-area SBA is bent, the sub-area SBA may overlap the main area MA in the thickness direction (the third direction DR3). The sub-area SBA may include the display driving circuit 200 and a pad portion electrically connected to the circuit board 300.

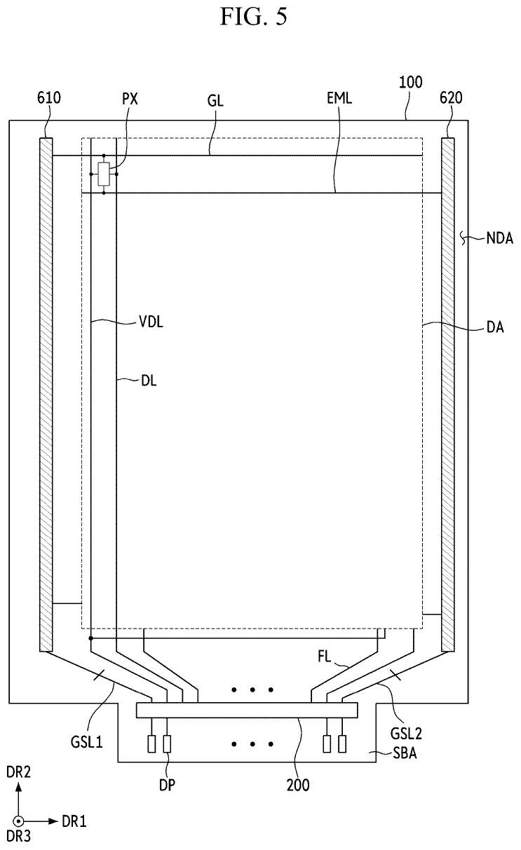

FIG. 5 is a plan view illustrating a display unit of a display device according to some embodiments of the present disclosure.

Referring to FIG. 5, the display area DA may include a plurality of pixels PX, and a plurality of first driving voltage lines VDL, a plurality of second driving voltage lines, a plurality of gate lines GL, a plurality of light emission control lines EML, and a plurality of data lines DL, which are connected to the plurality of pixels PX.

Each of the plurality of pixels PX may be connected to one gate line GL, one data line DL, one light emission control line EML, one driving voltage line VDL, and one second driving voltage line. Each of the pixels PX may include at least one thin film transistor, a light emitting element, and a capacitor.

The gate lines GL may extend in the first direction DR1, and may be spaced apart from each other in the second direction DR2 crossing the first direction DR1. The gate lines GL may be arranged along the second direction DR2. The gate lines GL may sequentially supply gate signals to the pixels PX for each of the first or second direction DR1 or DR2.

The light emission control lines EML may extend in the first direction DR1, and may be spaced apart from each other in the second direction DR2 (e.g., at regular intervals). The light emission control lines EML may be arranged along the second direction DR2. The light emission control lines EML may supply light emission timing signals (e.g., sequentially supply light emission timing signals) to the pixels PX for each of the first or second direction DR1 or DR2.

The data lines DL may extend in the second direction DR2, and may be spaced apart from each other in the first direction DR1 (e.g., at regular intervals). The data lines DL may be arranged along the first direction DR1. The data lines DL may supply data voltages (e.g., sequentially supply data voltages) to the pixels PX in the second direction DR2. The data voltage may determine luminance of each of the pixels PX.

The first driving voltage lines VDL may extend in the second direction DR2, and may be spaced apart from each other in the first direction DR1 (e.g., at regular intervals). The first driving voltage lines VDL may be arranged along the first direction DR1. The first driving voltage lines VDL may supply a first driving voltage to the plurality of pixels PX. The first driving voltage may be a high potential voltage for driving the light emitting elements of the pixels PX. In addition, second driving voltage lines for supplying a low-potential second driving voltage to the plurality of pixels PX may be further formed.

The non-display area NDA may surround the display area DA. The non-display area NDA may include a scan driver 610, a light emission control driver 620, fan-out lines FL, a first gate control line GSL1, and a second gate control line GSL2.

The fan-out lines FL may extend from the display driving circuit 200 to the display area DA. The fan-out lines FL may supply the data voltages received from the display driving circuit 200 to the plurality of data lines DL.

The first gate control line GSL1 may extend from signal pads of the display driving circuit 200 to signal terminals of the scan driver 610. The first gate control lines GSL1 may supply the first gate control signals GCS1 received from the display driving circuit 200 through the signal pads to the signal terminals of the scan driver 610.

The second gate control line GSL2 may extend from the signal pads of the display driving circuit 200 to the signal terminals of the light emission control driver 620. The second gate control lines GSL2 may supply light emission control signals ECS received from the display driving circuit 200 through the signal pads to the signal terminals of the light emission control driver 620.

The sub-area SBA may extend from one side of the non-display area NDA. The sub-area SBA may include a display driving circuit 200 and a pad portion DP. The pad portion DP may be arranged to be more adjacent to one side edge of the sub-area SBA than the display driving circuit 200. The pad portion DP may be electrically connected to the circuit board 300 through an anisotropic conductive film ACF.

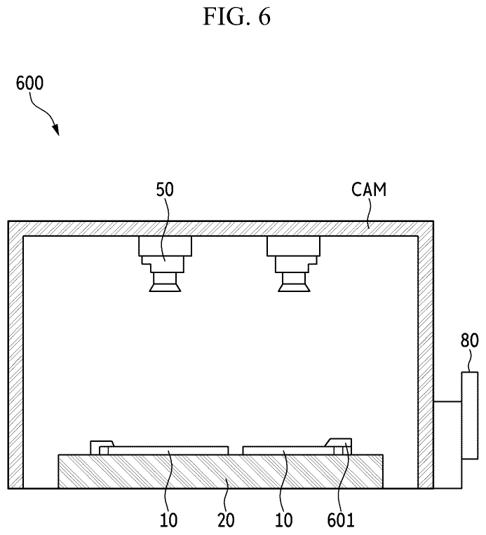

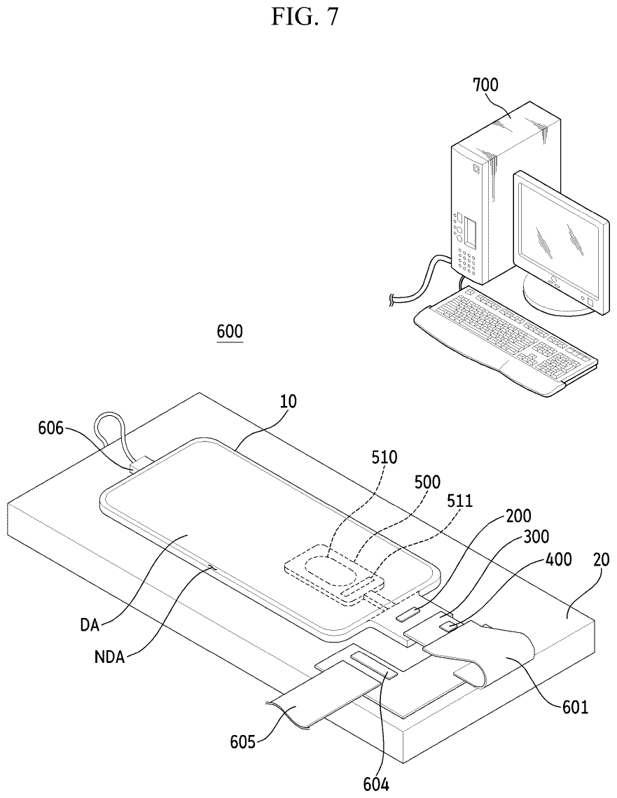

FIG. 6 is one side cross-sectional view illustrating an inspection device for a display device according to some embodiments of the present disclosure. FIG. 7 is a perspective view illustrating a loading state of a display device shown in FIG. 6 and an inspection process using an inspection device and an analysis device, according to some embodiments of the present disclosure.

Referring to FIGS. 6 and 7, an inspection device 600 of an inspecting system for a display device according to some embodiments includes a chamber CAM, a temperature control device 80, a loading plate 20, an input/output terminal unit 602, an inspection processing circuit 604, and an image detection device 50.

The analysis device of the inspecting system includes a quality analysis device 700 including a central processing unit such as a microprocessor, and a monitor. The quality analysis device 700 may be configured as a laptop computer or a personal computer.

The chamber CAM of the inspection device 600 establishes (e.g., defines) and maintains an external inspection environment of the display devices 10. For example, the chamber CAM may be formed in a three-dimensional structure having a polygonal shape so that an inspection space is provided therein and formed into an inspection environment such as a dark room or a vacuum. An opening/closing door capable of moving the display device 10 through a passage may be further formed on at least one sidewall or an upper surface of the chamber CAM. The display device 10 moves to the inside or the outside of the chamber CAM through the opening/closing door, and is loaded on or unloaded from the loading plate 20 before and after image display characteristics are inspected.

The loading plate 20 is arranged on a lower surface in the inspection space inside the chamber CAM.

At least one image detection device 50 including an ultrasonic image camera, a CMOS imaging camera, a digital camera, or the like may be arranged on an upper surface or a sidewall in the inspection space inside the chamber CAM.

The loading plate 20 may be arranged in the inspection space inside the chamber CAM, particularly on a lower surface inside the chamber CAM. When image display characteristics of the display panel are inspected, the display device 10 is loaded on the loading plate 20 by a separate transfer device or the like. Particularly, when image display characteristics of a plurality of display devices 10 are inspected, the display devices 10 may be transferred by a transfer device or the like and loaded on the loading plate 20. When image display characteristics of the display devices 10 are completely inspected, the completely inspected display devices 10 are unloaded to the outside of the chamber CAM by the transfer device or an inspector.

The temperature control device 80 may be installed on one sidewall or a lower or upper direction of the chamber CAM in a form that passes through the inside and the outside of the chamber CAM. The temperature control device 80 includes an air blower, a cooler, and a heater, and adjusts an internal temperature of the chamber CAM under the control of a main controller such as the inspection processing circuit 604 or the quality analysis device 700.

An input/output terminal unit 601 is connected to one sidewall inside the loading plate 20 or the chamber CAM, and thus is electrically connected to the circuit board 300 of the display devices 10 loaded on the loading plate 20.

The input/output terminal unit 601 supplies inspection pattern image data and timing signals, which are received from the inspection processing circuit 604, to the circuit board 300 of the display device 10. Then, the input/output terminal unit 601 transmits temperature data received through the display driving circuit 200 or the sensor control circuit 400 and the circuit board 300 of each display device 10 to the inspection processing circuit 604.

The inspection processing circuit 604 of the inspection device 600 supplies the inspection pattern image data and the timing signals to the display device 10 through the input/output terminal unit 601 during an inspection period. The timing signals are signals for setting an image display timing so that the display driving circuit 200 of the display device 10 controls the image display operation, and may include vertical and horizontal synchronization signals, data enable signals, and the like.

In the inspection step, the inspection processing circuit 604 first supplies the timing signals to the display device 10 through the input/output terminal unit 601. The inspection processing circuit 604 reads the temperature data from the sensor control circuit 400 of the display device 10 through the input/output terminal unit 601.

The inspection processing circuit 604 detects and analyzes temperature information of the display device 10 through the temperature data read in real time from the sensor control circuit 400 of the display device 10 to monitor a temperature change of the display device 10. The inspection processing circuit 604 analyzes a real-time temperature of the display device 10 and a range of the temperature changed in real time. The inspection processing circuit 604 transmits the temperature information and the temperature range information of the corresponding display device 10 to the quality analysis device 700 in real time.

The display driving circuit 200 of the display device 10 stores reference temperature information (e.g., 1st to (n)th reference temperature information; ‘n’ being a positive integer) first received from the inspection processing circuit 604 during the inspection period and inspection pattern image data for each temperature range in an internal memory or a separate external memory. The inspection pattern image data for each temperature range includes inspection pattern image data of a high gray scale, an intermediate or mixed gray scale, and a low gray scale, which are selected in accordance with (e.g., based on) the temperature range.

The display driving circuit 200 compares reference temperature information (e.g., first to fourth reference temperature information) with the temperature information of the display panel 100 according to (e.g., based on) the temperature data of the sensor control circuit 400 during the inspection period. Then, the display driving circuit 200 monitors a temperature change of the display panel in real time by analyzing the temperature range of the temperature information according to the temperature data as compared to the first to (n)th reference temperature information.

For example, the display driving circuit 200 analyzes the real-time temperature of the display panel 100 and the range information of the temperature changed in real time compared to the reference temperature information. In addition, the display driving circuit 200 selects inspection pattern image data of a preset gray scale range to correspond to the temperature range of the display panel 100, modulates (e.g., converts) the selected inspection pattern image data into analog data voltages, and supplies the modulated analog data voltages (e.g., the converted analog data voltages) to the pixels of the display area DA. Also, the display driving circuit 200 sequentially supplies scan signals to the pixels of the display area DA to control the image display timing so that the pixels sequentially display images.

For example, the display driving circuit 200 receives the temperature data of the display panel 100 in real time during the inspection period to detect the temperature information of the display panel 100, and compares the detected temperature of the display panel 100 with preset first to fourth reference temperature information.

When the detected temperature of the display device 10 is lower than the preset first reference temperature, the display driving circuit 200 transmits a first temperature code for a temperature lower than the first reference temperature to the inspection processing circuit 604. Accordingly, the inspection processing circuit 604 transmits a temperature increase code and a temperature increase control signal according to (e.g., based on) the first temperature code to the temperature control device 80 and the quality analysis device 700. The quality analysis device 700 and the temperature control device 80 increase or control the temperature inside the chamber CAM in response to the temperature increase code according to the first temperature code. The detected temperature of the display device 10 may be increased to the first reference temperature by the temperature increase control of the quality analysis device 700 and the temperature control device 80.

Afterwards, when the detected temperature of the display panel 100 is in a first reference temperature range, which is a range from the first reference temperature to less than the second reference temperature, the display driving circuit 200 selects inspection pattern image data of a preset high gray scale in at least one frame unit. The display driving circuit 200 modulates (e.g., converts) the inspection pattern image data of the high gray scale into analog data voltages and supplies the modulated analog data voltages (e.g., the converted analog data voltages) to the pixels of the display area DA. In such examples, the display driving circuit 200 supplies the scan signals to the pixels of the display area DA and controls the image display timing so that the pixels sequentially display images. Then, the display driving circuit 200 transmits a second temperature code according to (e.g., corresponding to or associated with) the first reference temperature range to the inspection processing circuit 604.

The quality analysis device 700 receives the second temperature code through the inspection processing circuit 604 and transmits a photographing control signal to the image detection device 50 to control operations such as ultrasonic image photographing and image photographing of the image detection device 50.

The image detection device 50 photographs the display images of the display devices 10 during the inspection period in accordance with (e.g., based on) the photographing control signal of the quality analysis device 700, and transmits the image data of the display images photographed in real time to the quality analysis device 700. Accordingly, the quality analysis device 700 analyzes (e.g., precisely analyzes) the photographed image data of each display device 10, which are received from the image detection device 50, in at least one pixel data unit and inspects the image display quality of each display device 10.

In the inspection process, when the detected temperature of the display panel 100 is in a second reference temperature range, which is a range from the second reference temperature to less than the third reference temperature, the display driving circuit 200 selects inspection pattern image data of a preset intermediate or mixed gray scale in at least one frame unit. The display driving circuit 200 modulates (e.g., converts) the selected inspection pattern image data of the intermediate or mixed gray scale into analog data voltages and supplies the modulated analog data voltages (e.g., the converted analog data voltages) to the pixels of the display area DA. Subsequently, the display driving circuit 200 supplies the scan signals to the pixels of the display area DA and controls the image display timing so that the pixels sequentially display images. Then, the display driving circuit 200 transmits a third temperature code according to (e.g., corresponding to or associated with) the second reference temperature range to the inspection processing circuit 604.

Even during the inspection pattern image display period of the intermediate or mixed gray scale, the quality analysis device 700 analyzes (e.g., precisely analyzes) the photographed image data of each display device 10, which are received from the image detection device 50, in at least one pixel data unit and inspects image display quality of each display device 10.

Furthermore, when the detected temperature of the display panel 100 is in a third reference temperature range, which is a range from the third reference temperature to less than the fourth reference temperature, the display driving circuit 200 selects inspection pattern image data of a preset low gray scale in at least one frame unit. The display driving circuit 200 modulates (e.g., converts) the selected inspection pattern image data of the low gray scale into analog data voltages and supplies the modulated analog data voltages (e.g., the converted analog data voltages) to the pixels of the display area DA. Subsequently, the display driving circuit 200 supplies the scan signals to the pixels of the display area DA and controls the image display timing so that the pixels sequentially display images. Then, the display driving circuit 200 transmits a fourth temperature code according to (e.g., corresponding to or associated with) the third reference temperature range to the inspection processing circuit 604.

Even during the inspection pattern image display period of the low gray scale, the quality analysis device 700 analyzes (e.g., precisely analyzes) the photographed image data of each display device 10, which are received from the image detection device 50, in at least one pixel data unit and inspects image display quality of each display device 10.

When the detected temperature of the display panel 100 is in a fourth reference temperature range greater than or equal to the preset fourth reference temperature, the display driving circuit 200 transmits a fifth temperature code according to (e.g., corresponding to or associated with) the fourth reference temperature range to the inspection processing circuit 604.

The inspection processing circuit 604 transmits an inspection stop signal according to (e.g., based on) the fifth temperature code to the image detection device 50 and the quality analysis device 700, and stops the image display operation of the display device 10 by blocking the supply of power to the display device 10.

The image detection device 50 photographs display images of the display devices 10 in accordance with (e.g., based on) the photographing control signal of the quality analysis device 700. To this end, the image detection device 50 may include an ultrasonic image camera, a CMOS photographing camera, a digital camera, or the like. The image detection device 50 photographs the display images of the display devices 10 in accordance with the photographing control signal of the quality analysis device 700 during an image display characteristic inspection period of the display device 10 and transmits image data of display images photographed in real time to the quality analysis device 700.

The quality analysis device 700 analyzes (e.g., precisely analyzes) the photographed image data of each display device 10, which are received from the image detection device 50, in at least one pixel data unit and inspects image display quality of each display device 10. As an example, the quality analysis device 700 may sequentially compare image data for each pixel, which includes luminance and gray scale information of each pixel, with image data of adjacent pixels or preset reference gray scale image data, so as to detect a luminance and gray scale display state for each pixel and whether each pixel is defective. The quality analysis device 700 determines whether each display device 10 is defective or good in accordance with (e.g., based on) a result of analysis of the photographed image data.

The quality analysis device 700 supplies a temperature control signal to the temperature control device 80 during the image display characteristic inspection period of each display device 10 to control the internal temperature of the chamber CAM within a preset inspection reference temperature range through the temperature control device 80. When the inspection stop signal is received from the inspection processing circuit 604, the quality analysis device 700 stops analyzing the image display characteristics. In addition, the quality analysis device 700 supplies a cooling control signal for lowering the internal temperature of the chamber CAM below a preset reference temperature to the temperature control device 80 to lower the internal temperature of the chamber CAM and temperatures of the loading plate 20 and the display device 10.

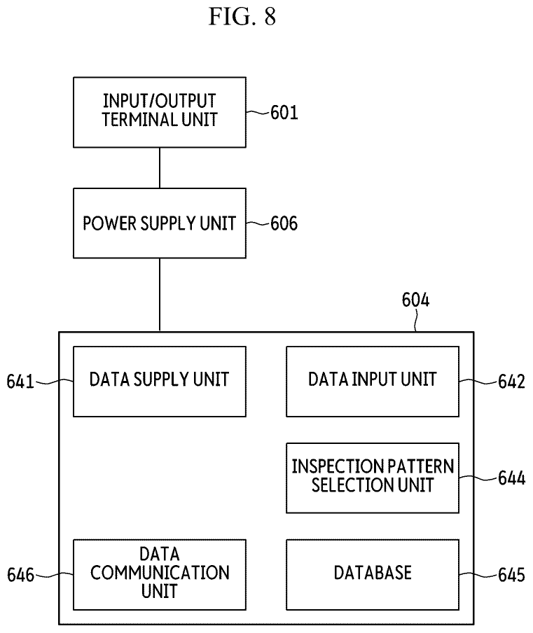

FIG. 8 is a schematic block diagram briefly illustrating components of the inspection device shown in FIG. 7, according to some embodiments of the present disclosure. In detail, FIG. 8 is a block diagram illustrating detailed components of the input/output terminal unit 601, the power supply unit 606, and the inspection processing circuit 604 of the inspection device 600.

The power supply unit 606 supplies preset power signals to the display device 10 or the display panel 100, and the sensor control circuit 400.

The input/output terminal unit 601 is electrically connected to the circuit board of the display devices 10 loaded on the loading plate 20. The input/output terminal unit 601 supplies the inspection pattern image data and timing signals, which are received from the inspection processing circuit 604, to the circuit board of the display device 10. In addition, the input/output terminal unit 601 transmits the temperature data received through the display driving circuit 200 or the sensor control circuit 400 and the circuit board 300 of each display device 10 to the inspection processing circuit 604.

The inspection processing circuit 604 includes a data supply unit 641, a data input unit 642, an inspection pattern selection unit 644, a database 645, and a data communication unit 646.

The data supply unit 641 supplies inspection pattern image data of a preset gray scale range and timing signals to the display driving circuit 200 of the display device 10 through the input/output terminal unit 601.

For example, when the image display characteristic inspection period of the display device 10 starts, the data supply unit 641 supplies the inspection pattern image data of a preset gray scale range, which are input by at least one horizontal line or frame unit from the inspection pattern selection unit 644, to the display device 10. The data supply unit 641 supplies the timing signals (e.g., vertical and horizontal synchronization signals and a data enable signal) to at least one display device 10 through the input/output terminal unit 602. In such examples, the inspection pattern image data of a preset gray scale range may be input and output by being divided into inspection pattern image data of a preset high gray scale, inspection pattern image data of an intermediate or mixed gray scale, and inspection pattern image data of a low gray scale, respectively.

The data input unit 642 reads temperature data from the sensor control circuit 400 of the display device 10 in real time through the input/output terminal unit 601. As described above, the sensor control circuit 400 of each display device 10 modulates (e.g., converts) an analog temperature sensing signal into digital temperature data and calculates rear surface temperature information of the fingerprint sensing pad 510 or the display panel 100 in real time. Accordingly, the data input unit 642 reads temperature data from the sensor control circuit 400 through the input/output terminal unit 602 electrically connected to a data output terminal of the sensor control circuit 400. In such examples, the temperature data of the sensor control circuit 400, which are read in real time, are shared with the inspection pattern selection unit 644.

The inspection pattern selection unit 644 sequentially reads the inspection pattern image data of a preset gray scale range from the database 645, aligns the inspection pattern image data in at least one frame unit, and transmits the inspection pattern image data to the data input unit 642.

When the detected temperature of the display device 10 is greater than or equal to a preset specific reference temperature, the inspection pattern selection unit 644 generates a photographing control signal and an inspection stop signal, respectively, and transmits the same to the data communication unit 646. In addition, the inspection pattern selection unit 644 may additionally generate a cooling control signal and transmit the generated cooling control signal to the quality analysis device 700 through the data communication unit 646.

The inspection pattern selection unit 644 may turn off the power of the display device 10 when the detected temperature of the display device 10 is greater than or equal to the preset specific reference temperature.

The data communication unit 646 transmits the photographing control signal or the inspection stop signal to the image detection device 50 during the image display characteristic inspection period of the display device 10 under the control of the inspection pattern selection unit 644, and transmits the cooling control signal or the inspection stop signal to the quality analysis device 700. The data communication unit 646 includes a wired or wireless communication module capable of performing short-range communication, thereby performing LAN, Bluetooth, Wi-Fi, LTE or 5G communication.

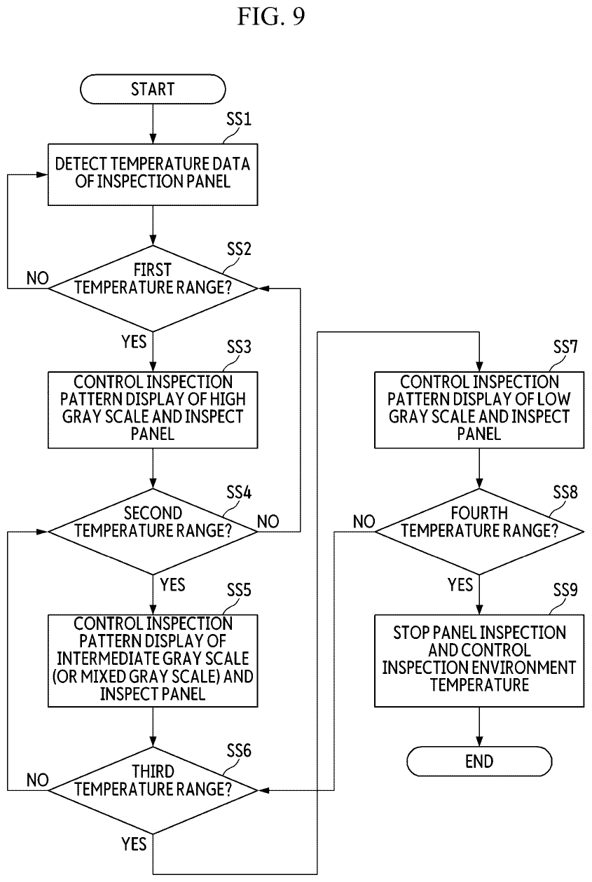

FIG. 9 is a flow chart illustrating an inspecting method of an image display of a display device according to some embodiments of the present disclosure.

Referring to FIG. 9, a module-type display device 10 in which driving circuit units such as the display driving circuit 200, the circuit board 300, and the sensor control circuit 400 are assembled and connected to the display panel 100 is loaded on the loading plate 20 of the chamber CAM during the image display characteristic inspection period of each display device 10.

The data supply unit 641 of the inspection processing circuit 604 supplies reference temperature information (e.g., first to fourth reference temperature information) and inspection pattern image data for each temperature range to at least one display device 10 through the input/output terminal unit 602 during the inspection period. Accordingly, the display driving circuit 200 of each display device 10 stores reference temperature information and inspection pattern image data for each temperature range, which are first received from the inspection processing circuit 604, in an internal memory or a separate external memory.

Subsequently, the display driving circuit 200 analyzes the temperature information of the display panel 100 and the temperature range compared to the reference temperature information in real time through the temperature data of the display panel 100, which is received through the sensor control circuit 400 during the inspection period. The inspection processing circuit 604 receives the temperature data in real time through the sensor control circuit 400 and monitors a temperature change of the display panel 100 (SS1).

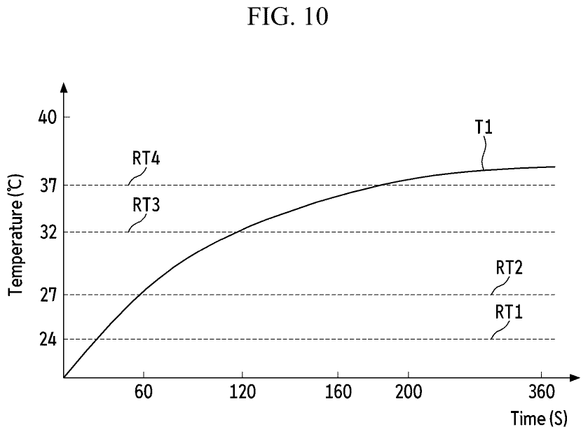

FIG. 10 is a graph illustrating a temperature change of a display panel and first to fourth reference temperature ranges according to some embodiments of the present disclosure.

Referring to FIGS. 9 and 10, the display driving circuit 200 of the display device 10 transmits a first temperature code for a temperature lower than a preset first reference temperature to the inspection processing circuit 604 during a period at which the detected temperature of the display device 10 is lower than the preset first reference temperature. Accordingly, the inspection processing circuit 604 may transmit a control signal including a temperature increase code to the temperature control device 80 and the quality analysis device 700. As a result, the detected temperature of the display device 10 may increase to a first reference temperature RT1 by the temperature increase control of the quality analysis device 700 and the temperature control device 80 (SS2).

When the detected temperature of the display device 10 is in a first reference temperature range, which is a range from the first reference temperature RT1 to less than a second reference temperature RT2, the display driving circuit 200 selects inspection pattern image data of a preset and stored high gray scale in at least one frame unit. The display driving circuit 200 modulates (e.g., converts) the inspection pattern image data of a high gray scale into analog data voltages and supplies the modulated analog data voltages (e.g., the converted analog data voltages) to the pixels of the display area DA. In such examples, the display driving circuit 200 supplies the scan signals to the pixels of the display area DA and controls the image display timing so that the pixels sequentially display images. Then, the display driving circuit 200 transmits a second temperature code according to (e.g., corresponding to or associated with) the first reference temperature range to the inspection processing circuit 604.

For example, the inspection pattern image data of the high gray scale may be image data in which gray scale data in the range of 201 gray scale to 255 gray scale, which indicates high luminance and brightness of the high gray scale, from the range of 0 gray scale to 255 gray scale are combined in a preset pattern. For example, the inspection pattern image data of the high gray scale may be image data in which the data of 200 gray scale, 250 gray scale, and 255 gray scale are repeatedly arranged to be alternate with one another in a vertical or horizontal stripe shape, or are repeatedly arranged to be alternate with one another in a circular shape.

The inspection pattern image of the high gray scale is displayed on the display area DA of the display panel 100 under the control of the display driving circuit 200. In such examples, the image detection device 50 photographs the display images of the display devices 10 during the inspection period in accordance with (e.g., based on) the photographing control signal of the quality analysis device 700, and transmits the image data of the display images photographed in real time to the quality analysis device 700. Accordingly, the quality analysis device 700 analyzes (e.g., precisely analyzes) the photographed image data of each display device 10, which are received from the image detection device 50, in at least one pixel data unit and inspects the image display quality of each display device 10 (SS3).

In the inspection process, when the detected temperature of the display panel 100 is in a second reference temperature range, which is a range from the second reference temperature to less than the third reference temperature, the display driving circuit 200 selects inspection pattern image data of a preset intermediate or mixed gray scale in at least one frame unit. The display driving circuit 200 modulates (e.g., converts) the selected inspection pattern image data of the intermediate or mixed gray scale into analog data voltages and supplies the modulated analog data voltages (e.g., the converted analog data voltages) to the pixels of the display area DA. Subsequently, the display driving circuit 200 supplies the scan signals to the pixels of the display area DA and controls the image display timing so that the pixels sequentially display images. Then, the display driving circuit 200 transmits a third temperature code according to (e.g., corresponding to or associated with) the second reference temperature range to the inspection processing circuit 604.

For example, the inspection pattern image data of the intermediate or mixed gray scale may be image data in which gray scale data in the range of 101 gray scale to 199 gray scale, which indicates brightness of the intermediate gray scale, from the range of 0 gray scale to 255 gray scale are combined in a preset pattern. For example, the inspection pattern image data of the intermediate or mixed gray scale may be image data in which the data of 101 gray scale, 130 gray scale, 160 gray scale and 199 gray scale are repeatedly arranged to be alternate with one another in a vertical or horizontal stripe shape, or are repeatedly arranged to be alternate with one another in a circular shape.

Even during the inspection pattern image display period of the intermediate or mixed gray scale, the quality analysis device 700 analyzes (e.g., precisely analyzes) the photographed image data of each display device 10, which are received from the image detection device 50, in at least one pixel data unit and inspects image display quality of each display device 10. In this way, when the detected temperature of the display device 10 gradually increases and reaches the second reference temperature range, the display driving circuit 200 displays the inspection pattern image of the intermediate or mixed gray scale on the display panel 100 so that the temperature increase rate of the display panel 100 decreases.

The display driving circuit 200 may extend the period during which the display panel 100 is maintained in the second reference temperature range by displaying the inspection pattern image of the intermediate or mixed gray scale on the display panel 100 to slow the temperature increase rate of the display panel 100. Accordingly, the image display characteristic inspection period of the display panel 100 may be extended or adjusted (SS4).

The inspection pattern image of the intermediate or mixed gray scale is displayed on the display area DA of the display panel 100 under the control of the display driving circuit 200. In such examples, the image detection device 50 photographs the display images of the display devices 10 during the inspection period in accordance with (e.g., based on) the photographing control signal of the quality analysis device 700, and transmits the image data of the display images photographed in real time to the quality analysis device 700. Accordingly, the quality analysis device 700 analyzes (e.g., precisely analyzes) the photographed image data of each display device 10, which are received from the image detection device 50, in at least one pixel data unit and inspects the image display quality of each display device 10 (SS5).

Afterwards, when the detected temperature of the display panel 100 is in a third reference temperature range, which is a range from the third reference temperature to less than the fourth reference temperature, the display driving circuit 200 selects inspection pattern image data of a preset low gray scale in at least one frame unit. The display driving circuit 200 modulates (e.g., converts) the selected inspection pattern image data of the low gray scale into analog data voltages and supplies the modulated analog data voltages (e.g., converted analog data voltages) to the pixels of the display area DA. Subsequently, the display driving circuit 200 supplies the scan signals to the pixels of the display area DA and controls the image display timing so that the pixels sequentially display images. Then, the display driving circuit 200 transmits a fourth temperature code according to (e.g., corresponding to or associated with) the third reference temperature range to the inspection processing circuit 604 (SS6).

For example, the inspection pattern image data of the low gray scale may be image data in which gray scale data in the range of 0 gray scale to 99 gray scale, which indicates brightness of the low gray scale, from the range of 0 gray scale to 255 gray scale are combined in a preset pattern. For example, the inspection pattern image data of the low gray scale may be image data in which the data of 30 gray scale, 60 gray scale and 99 gray scale are repeatedly arranged to be alternate with one another in a vertical or horizontal stripe shape, or are repeatedly arranged to be alternate with one another in a circular shape.

When the detected temperature of the display device 10 continues to increase and reaches the third reference temperature range, the display driving circuit 200 displays the inspection pattern image of the low gray scale on the display panel 100 so that the temperature increase rate of the display panel 100 decreases. The display driving circuit 200 may extend the period during which the display panel 100 is maintained in the third reference temperature range by displaying the inspection pattern image of the low gray scale on the display panel 100 to slow the temperature increase rate of the display panel 100. Accordingly, the image display characteristic inspection period of the display panel 100 may be extended or adjusted.

Even during the inspection pattern image display period of the low gray scale, the image detection device 50 photographs the display images of the display devices 10 for the inspection period in accordance with (e.g., based on) the photographing control signal of the quality analysis device 700, and transmits the image data of the display images photographed in real time to the quality analysis device 700. Accordingly, the quality analysis device 700 analyzes (e.g., precisely analyzes) the photographed image data of each display device 10, which are received from the image detection device 50, in at least one pixel data unit and inspects the image display quality of each display device 10 (SS7).

When the detected temperature of the display panel 100 is in a fourth reference temperature range greater than or equal to the preset fourth reference temperature, the display driving circuit 200 transmits a fifth temperature code according to (e.g., corresponding to or associated with) the fourth reference temperature range to the inspection processing circuit 604.

The inspection processing circuit 604 transmits an inspection stop signal according to (e.g., based on) the fifth temperature code to the image detection device 50 and the quality analysis device 700, and stops the image display operation of the display device 10 by blocking the supply of power to the display device 10.

For example, when the detected temperature of the display device 10 is in a fourth reference temperature range equal to or greater than a preset fourth reference temperature RT4, the inspection pattern selection unit 644 transmits the inspection stop signal to the image detection device 50 and the quality analysis device 700, and stops the image display operation of the display device 10. In such examples, a panel driving controller 643 may stop supplying driving control signals and turn off the power of the display device 10.

When the inspection stop signal is received from the inspection processing circuit 604, the quality analysis device 700 stops analyzing the image display characteristics. In addition, the quality analysis device 700 supplies a cooling control signal for lowering the internal temperature of the chamber CAM to be lower than a preset reference temperature to the temperature control device 80, thereby lowering the internal temperature of the chamber CAM and temperatures of the loading plate 20 and the display device 10.

In concluding the detailed description, those skilled in the art will appreciate that many variations and modifications can be made to the preferred embodiments without substantially departing from the principles of the present disclosure. Therefore, the disclosed embodiments of the present disclosure are used in a generic and descriptive sense only and not for purposes of limitation.

What is claimed is:

1. A display device comprising:
a display panel having a display area and configured to display an image through pixels of a display area;
a fingerprint sensing circuit embedded into the display panel and configured to sense a user's fingerprint;
a sensor control circuit configured to receiving a temperature sensing signal from a temperature sensing element of the fingerprint sensing circuit, and to generate temperature data in real time; and
a display driving circuit configured to:
receive and store first to (n)th reference temperature information and inspection pattern image data for each temperature range from the outside,
analyze temperature information and a temperature change for the display panel in real time by receiving the temperature data in real time,
select one of the inspection pattern image data based on a comparison result of the temperature information for the display panel and the first to (n)th reference temperature information, and
display the one of the inspection pattern image data on the display panel as an image.

2. The display device of claim 1, wherein the fingerprint sensing circuit is embedded into a non-display area on one side or a rear surface of the display panel or in a direction of the rear surface of the display panel,
wherein the fingerprint sensing circuit further comprises a fingerprint sensing pad configured to sense light reflected from a user's finger by using light emitting elements and light receiving elements, which are arranged in a matrix structure, and
wherein the fingerprint sensing circuit is further configured to supply light sensing signals of the fingerprint sensing pad and the temperature sensing signal of the temperature sensing element to the sensor control circuit.

3. The display device of claim 1, wherein the display driving circuit is further configured to store the first to (n)th reference temperature information and the inspection pattern image data for each temperature range, which are received from an external inspection processing circuit during an inspection period, in an internal memory or a separate external memory, and
wherein the inspection pattern image data for each temperature range comprises inspection pattern image data of a high gray scale, an intermediate or mixed gray scale, and a low gray scale, which are selected based on the temperature range.

4. The display device of claim 3, wherein the display driving circuit is configured to:
analyze the temperature range of the temperature information according to the temperature data compared to the first to (n)th reference temperature information,
select at least one inspection pattern image data from the inspection pattern image data of a preset gray scale range based on the temperature range of the display panel, which is analyzed in real time, and
control an image display timing so that an image according to the at least one inspection pattern image data is displayed on the display area.

5. The display device of claim 3, wherein the display driving circuit is further configured to:
transmit a first temperature code to an inspection processing circuit of an inspection device in response to a temperature of the temperature information for the display panel being lower than a preset first reference temperature, and
drive the pixels of the display area so that inspection pattern image data of a preset high gray scale among the inspection pattern image data is displayed on the display area in response to the temperature of the temperature information for the display panel being in a first reference temperature range, which is a range from the preset first reference temperature to less than a second reference temperature, and
transmit a second temperature code according to the first reference temperature range to the inspection processing circuit.

6. The display device of claim 5, wherein the display driving circuit is configured to:
drive the pixels of the display area so that inspection pattern image data of a preset intermediate or mixed gray scale among the inspection pattern image data is displayed on the display area when the temperature of the temperature information for the display panel is detected in a second reference temperature range, which is a range from the second reference temperature to less than a third reference temperature, and transmits a third temperature code according to the second reference temperature range to the inspection processing circuit, and
drive the pixels of the display area so that inspection pattern image data of a preset low gray scale among the inspection pattern image data is displayed on the display area in response to the temperature of the temperature information for the display panel being in a third reference temperature range, which is a range from the third reference temperature to less than a fourth reference temperature, and
transmit a fourth temperature code according to the third reference temperature range to the inspection processing circuit.

7. The display device of claim 5, wherein the display driving circuit is configured to transmit a fifth temperature code to the inspection processing circuit in response to the temperature of the temperature information for the display panel being in a fourth reference temperature range above a preset fourth reference temperature, and to stop an image display operation based on a power control operation of the inspection processing circuit.

8. An electronic device comprising:
a display device displaying an image;
an image signal processor configured to control an image display timing of the display device; and
a power module configured to provide a power signal to the display device,
wherein the display device comprises:
a display panel having a display area and configured to display an image through pixels of the display area;
a fingerprint sensing circuit embedded into the display panel and configured to sense a user's fingerprint;
a sensor control circuit configured to receive a temperature sensing signal from a temperature sensing element of the fingerprint sensing circuit and to generate temperature data in real time; and
a display driving circuit configured to:
receive and store first to (n)th reference temperature information and inspection pattern image data for each temperature range from the outside,
analyze temperature information and a temperature change for the display panel in real time by receiving the temperature data in real time,
select one of the inspection pattern image data based on a comparison result of the temperature information for the display panel and the first to (n)th reference temperature information, and
display the one of the selected inspection pattern image data on the display panel as an image.

9. An inspecting system for a display device, the inspecting system comprising:
a chamber establishing and maintaining an external inspection environment of the display device;
a temperature control device configured to control an internal temperature of the chamber;
a loading plate on which the display device is loaded;
an input/output terminal unit electrically connected to a circuit board of the display device;
an inspection processing circuit configured to supply inspection pattern image data of a preset gray scale range and timing signals to the display device through the input/output terminal unit, and to receive temperature data from the display device;
an image detection device configured to photograph a display image of the display device; and
a quality analysis device configured to:
inspect whether the display device is good,
supply a temperature control signal to the temperature control device during an image display characteristics inspection period of the display device to control the internal temperature of the chamber within a preset inspection reference temperature range,
stop analyzing image display characteristics of the display device in response to an inspection stop signal being received from the inspection processing circuit, and
control the internal temperature of the chamber by supplying a cooling control signal for lowering the internal temperature of the chamber to be lower than a preset reference temperature to the temperature control device.

10. The inspecting system of claim 9, wherein the display device comprises:
a display panel having a display area and configured to display an image through pixels of the display area;
a fingerprint sensing circuit embedded into the display panel and configured to sense a user's fingerprint;
a sensor control circuit configured to receive a temperature sensing signal from a temperature sensing element of the fingerprint sensing circuit and to generate temperature data in real time; and
a display driving circuit configured to receive and storing first to (n)th reference temperature information and inspection pattern image data for each temperature range from the outside, and to analyze temperature information and a temperature change for the display panel in real time by receiving the temperature data in real time,
wherein the display driving circuit is further configured to select one of the inspection pattern image data based on a comparison result of the temperature information for the display panel and the first to (n)th reference temperature information, and to display the one of the inspection pattern image data on the display panel as an image.

11. The inspecting system of claim 10, wherein the display driving circuit is further configured to store the first to (n)th reference temperature information and the inspection pattern image data for each temperature range, which are received from the inspection processing circuit during an inspection period, in an internal memory or a separate external memory, and
the inspection pattern image data for each temperature range comprise inspection pattern image data of a high gray scale, an intermediate or mixed gray scale, and a low gray scale, which are selected based on the temperature range.

12. The inspecting system of claim 11, wherein the display driving circuit is configured to:
analyze the temperature range of the temperature information according to the temperature data compared to the first to (n)th reference temperature information,
select at least one inspection pattern image data from the inspection pattern image data of a preset gray scale range based on the temperature range of the display panel, which is analyzed in real time, and
control an image display timing so that an image according to the selected inspection pattern image data is displayed on the display area.

13. The inspecting system of claim 12, wherein the inspection processing circuit is configured to:
receive the temperature data in real time from the sensor control circuit through the input/output terminal unit,
analyze the temperature information and the temperature change of the temperature data in real time, and
block a power supply of the display device based on a temperature analysis result.

14. The inspecting system of claim 12, wherein the display driving circuit is configured to:
transmit a first temperature code to an inspection processing circuit of an inspection device in response to a temperature of the temperature information for the display panel being at a temperature lower than a preset first reference temperature, and
drive the pixels of the display area so that inspection pattern image data of a preset high gray scale among the inspection pattern image data is displayed on the display area in response to the temperature of the temperature information for the display panel being in a first reference temperature range, which is a range from the first reference temperature to less than a second reference temperature, and
transmit a second temperature code according to the first reference temperature range to the inspection processing circuit.

15. The inspecting system of claim 14, wherein the display driving circuit is configured to:
drive the pixels of the display area so that inspection pattern image data of a preset intermediate or mixed gray scale among the inspection pattern image data is displayed on the display area, in response to the temperature of the temperature information for the display panel being in a second reference temperature range, which is a range from the second reference temperature to less than a third reference temperature,
transmit a third temperature code according to the second reference temperature range to the inspection processing circuit, and
drive the pixels of the display area so that inspection pattern image data of a preset low gray scale among the inspection pattern image data is displayed on the display area in response to the temperature of the temperature information for the display panel being in a third reference temperature range, which is a range from the third reference temperature to less than a fourth reference temperature, and
transmit a fourth temperature code according to the third reference temperature range to the inspection processing circuit.

16. The inspecting system of claim 15, wherein the display driving circuit is configured to:
transmit a fifth temperature code to the inspection processing circuit in response the temperature of the temperature information for the display panel being in a fourth reference temperature range above a preset fourth reference temperature, and
stop an image display operation based on a power control operation of the inspection processing circuit.
